(19) United States
(12) Patent Application Publication
(10) Pub. No.: US 2025/0246459 A1
(43) Pub. Date: Jul. 31, 2025

(54) MOUNTING APPARATUS, NOZZLE INSPECTION UNIT FOR THE MOUNTING APPARATUS, BAD NOZZLE EJECTION UNIT FOR THE MOUNTING APPARATUS

(71) Applicant: Samsung Electronics Co., Ltd., Suwon-si (KR)

(72) Inventors: Sangmyung LEE, Suwon-si (KR); Youna PARK, Changwon-si (KR); Minju KOH, Changwon-si (KR); Jepil LEE, Changwon-si (KR)

(73) Assignees: Samsung Electronics Co., Ltd., Suwon-si (KR); Hanwha Precision Machinery Co., Ltd., Changwon-si (KR)

(21) Appl. No.: 18/910,034

(22) Filed: Oct. 9, 2024

(30) Foreign Application Priority Data
Jan. 25, 2024 (KR) 10-2024-0011723

(51) Int. Cl. H01L 21/67; B08B 9/032

(52) U.S. Cl. CPC H01L 21/67144; B08B 9/0321; B08B 2209/032

(57) ABSTRACT

A mounting apparatus, a nozzle inspection unit for the mounting apparatus, and a bad nozzle ejection unit for the mounting apparatus are provided. The nozzle inspection unit includes a nozzle flux inspection portion configured to perform a flux inspection on an adsorption nozzle of the mounting apparatus, a foreign substance removal portion configured to remove foreign substances from the adsorption nozzle, and a tension measurement portion configured to measure a tension of a spring within the adsorption nozzle.

### CROSS-REFERENCE TO RELATED APPLICATION

This application is based on and claims priority under 35 U.S.C. § 119 to Korean Patent Application No. 10-2024-0011723, filed on Jan. 25, 2024, in the Korean Intellectual Property Office, the disclosure of which is incorporated by reference herein in its entirety.

### BACKGROUND

The inventive concepts relate to a mounting apparatus, a nozzle inspection unit for the mounting apparatus, and a bad nozzle ejection unit for the mounting apparatus.

Among semiconductor processes, surface-mount technology processes refer to processes for mounting devices on a printed circuit board (PCB). Mainly, devices such as capacitors, registers, semiconductor packages, etc. may be mounted on the PCB through such processes. In at least some of these processes, nozzles may adsorb passive devices and/or semiconductor packages and place the passive devices or semiconductor packages on the PCB.

However, during a pick-up operation process of the nozzles, the nozzles may become clogged due to foreign substances on the surfaces of the devices and/or packages, thereby decreasing the vacuum pressures within the nozzles, and damage to the nozzles themselves may occur due to long-term use, causing disadvantages (e.g., failing to pick up the devices or packages and/or dropping the devices or packages during mounting).

In this case, facilities may be stopped or pickup functions of bad nozzles may be limited. Additionally, facility stoppage or nozzle function restrictions may cause a decrease in the productivity of the entire process. Therefore, solutions thereto are being explored.

### SUMMARY

The inventive concepts provide a mounting apparatus, a nozzle inspection unit for the mounting apparatus, and a bad nozzle ejection unit for the mounting apparatus for inspecting a nozzle defect, replacing a bad nozzle with a good nozzle without stopping the mounting apparatus, and ejecting the bad nozzle to outside.

Also, a task to be solved by the inventive concepts is not limited to the task mentioned above, and other tasks can be clearly understood by those skilled in the art from the description below.

According to an aspect of the inventive concepts, there is provided a nozzle inspection device for a mounting apparatus including a nozzle flux inspection assembly configured to perform a flux inspection on an adsorption nozzle of the mounting apparatus, a foreign substance removal assembly configured to remove foreign substances from the adsorption nozzle, and a tension measurement assembly configured to measure a tension of a spring within the adsorption nozzle.

According to another aspect of the inventive concepts, there is provided a nozzle ejection device for a mounting apparatus including a nozzle separation assembly configured to separate an adsorption nozzle from a head device of the mounting apparatus, a nozzle ejection assembly configured to eject the adsorption nozzle separated by the nozzle separation portion, to outside of the mounting apparatus, and a nozzle transfer assembly configured to transfer the adsorption nozzle separated by the nozzle separation assembly, to the nozzle ejection assembly.

According to a further aspect of the inventive concepts, there is provided a mounting apparatus including a part supply device configured to supply parts to be mounted; a head device comprising an adsorption nozzle, the head device configured to load and unload the parts; a nozzle inspection device configured to inspect the adsorption nozzle and to remove foreign substances from the adsorption nozzle; a nozzle ejection device configured to eject the adsorption nozzle based on a determination that the inspected adsorption nozzle is abnormal; a nozzle exchange device configured to provide replaceable adsorption nozzles; and a controller configured to determine whether the adsorption nozzle is abnormal based on a result of the inspection of the adsorption nozzle by the nozzle inspection device, and to control the nozzle ejection device to eject the abnormal adsorption nozzle.

### BRIEF DESCRIPTION OF THE DRAWINGS

Embodiments will be more clearly understood from the following detailed description taken in conjunction with the accompanying drawings in which:

FIG. 1 is a construction diagram schematically illustrating a mounting apparatus according to at least one embodiment;

FIG. 2 is a side view schematically illustrating an example of a head unit of FIG. 1;

FIG. 3A is a perspective view schematically illustrating an example of a nozzle inspection unit of FIG. 1;

FIG. 3B is a perspective view schematically illustrating another example of a nozzle inspection unit of FIG. 1;

FIG. 4 is a construction diagram schematically illustrating a nozzle ejection unit of FIG. 1;

FIG. 5 is a plan view illustrating an example of a nozzle ejection unit of FIG. 1;

FIG. 6 is an enlarged view illustrating a portion A of FIG. 5; and

FIG. 7 is a side view schematically illustrating a nozzle ejection unit of FIG. 5.

### DETAILED DESCRIPTION OF THE EMBODIMENTS

Embodiments are described below in detail with reference to the attached drawings. The same reference numerals are used for the same components in the drawings, and a repeated description thereof is omitted.

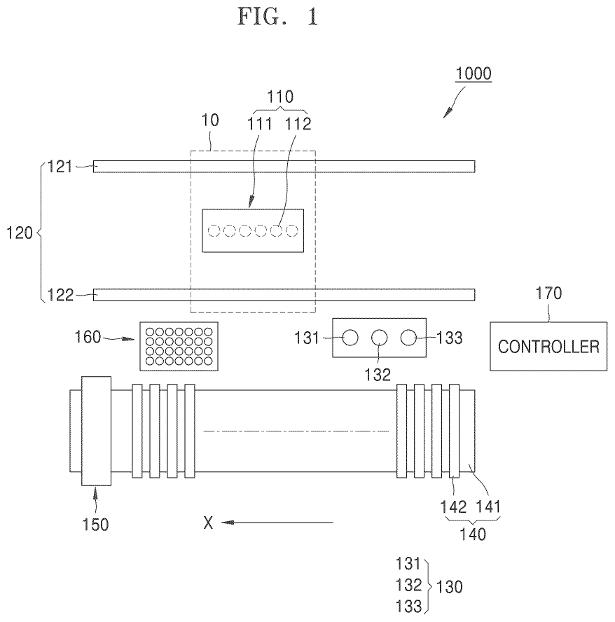

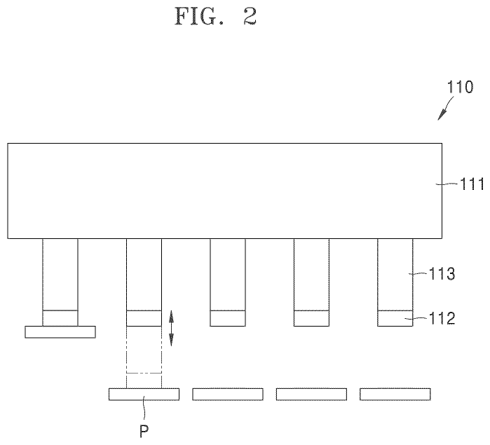

FIG. 1 is a construction diagram schematically illustrating a mounting apparatus according to at least one embodiment; and FIG. 2 is a side view schematically illustrating an example of the head unit of FIG. 1.

Referring to FIG. 1, a mounting apparatus 1000 according to at least one embodiment includes a head unit (or head device) 110, a substrate transfer unit (substrate transfer unit) 120, a nozzle inspection unit (or nozzle inspection device) 130, a part supply unit (or part supply device) 140, a nozzle ejection unit (or nozzle ejection device) 150, and a nozzle exchange unit (nozzle exchange device) 160 According to at least some embodiments, the mounting apparatus 1000 further includes and/or is connected to a controller 170 configured to control at least some of the operations of mounting apparatus 1000. The controller 170 may be implemented with and/or include processing circuitry including hardware, software, or a combination of hardware and software. For example, the processing circuitry more specifically may include, but is not limited to, a central processing unit (CPU), a neural processing unit (NPU), a graphics processing unit (GPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The head device 110 is configured to load and/or unload parts. For example, the head device 110 may load parts provided by the part supply device 140, and unload the parts onto the substrate 10. The head device 110 may unload the parts onto the substrate 10, thereby mounting the parts on the substrate 10.

Referring to FIG. 2, according to at least one embodiment, the head device 110 includes a main body portion (or main body assembly) 111, a mounting head 113, and an adsorption nozzle 112.

The mounting head 113 may be disposed on one face of the main body assembly 111 configured to face the substrate 10. A plurality of mounting heads 113 may be disposed on one face of the main body assembly 111 to form a line, to form a circle, and/or to form grid, and/or to form the like.

The mounting head 113 may be configured to move in an up/down direction relative the substrate 10. For example, an actuator for individually lifting one or more of the mounting heads 113 may be included within the main body assembly 111.

The adsorption nozzle 112 may be arranged at a lower end of the mounting head 113. According to at least some embodiments, the adsorption nozzle 112 is detachable from the mounting head 113. Negative pressure or positive pressure may be supplied to the adsorption nozzle 112 from an external air supply device through the mounting head 113. As the negative pressure is supplied to the adsorption nozzle 112, the adsorption nozzle 112 may adsorb (or load) a part P, and as the positive pressure is supplied to the adsorption nozzle 112, the adsorption nozzle 112 may unload the part P.

However, when foreign substances are caught in the adsorption nozzle 112, the pressure within the adsorption nozzle 112 may decrease and thereby not be sufficient to load the part P, and thus the adsorption nozzle 112 may fail to load the part P and/or properly unload the part P onto the substrate 10. In these cases, the operation of the mounting apparatus is stopped and the adsorption nozzle is replaced and/or cleaned, and/or a pickup function of the abnormal adsorption nozzle was restricted. As a result, in comparative cases, the productivity of a mounting process was decreased and a man-hour for maintenance was increased.

In contrast, according to at least one embodiment, the pressure within the adsorption nozzle 112 may be checked and when the pressure within the adsorption nozzle 112 is less than or equal to a predetermined value (e.g., a threshold value), the an inspection by the nozzle inspection device 130 may be initiated to determine whether the adsorption nozzle 112 is abnormal. In at least one example, the controller 170 may check the pressure within the adsorption nozzle 112 and control the nozzle inspection device 130 (e.g., initiate the inspection) based on a result of the check. An example of this is described in further detail below.

The substrate transfer device 120 is configured to position the substrate 10. For example, the substrate transfer device 120 may move the substrate 10 in a first direction X, bring in the substrate 10 to a predetermined working position, and take out the substrate 10 on which parts P are mounted in the predetermined working position. As an example, the substrate transfer device 120 may include a pair of transfer conveyor belts 121 and 122 and a conveyor driving motor (not shown) that drives the transfer conveyor belts 121 and 122. In at least some embodiments, the gap between the two transfer conveyor belts 121 and 122 may be adjusted depending on the size of the substrate 10.

The nozzle inspection device 130 is configured to inspect whether the adsorption nozzle 112 is potentially abnormal, and to remove foreign substances from the adsorption nozzle 112. The nozzle inspection device 130 may, for example, measure a flow rate of the adsorption nozzle 112 and, when the flow rate is less than or equal to a predetermined value, the nozzle inspection device 130 may remove foreign substances from the adsorption nozzle 112 by blowing, e.g., compressed air into the adsorption nozzle 112.

For example, the controller 170 may check the pressure within the adsorption nozzle 112 before the nozzle inspection device 130 inspects whether the adsorption nozzle 112 is abnormal, move the head device 110 to the nozzle inspection device 130 to allow the nozzle inspection device 130 to inspect whether the adsorption nozzle 112 of the head device 110 is abnormal when the pressure within the adsorption nozzle 112 is determined to be less than or equal to a predetermined value, and control the position of the adsorption nozzle 112 of the head device 110 such that the adsorption nozzle 112 is disposed on the nozzle inspection device 130. For example, in at least one embodiment, the controller 170 may be connected to and/or receive signals from a pressure monitor configured to check the pressure within the adsorption nozzle 112. The pressure monitor may include, for example, a flow rate monitor, a compression-type load cell, etc.

Further, when the flow rate of the adsorption nozzle 112 is less than or equal to a predetermined value as an inspection result of the nozzle inspection device 130, the controller 170 may control the nozzle inspection device 130 to blow compressed air into the adsorption nozzle 112 and thereby remove foreign substances from the adsorption nozzle 112. After the nozzle inspection device 130 blows compressed air into the adsorption nozzle 112, the controller 170 may determine the flow rate of the adsorption nozzle 112 again. For example, in at least some embodiments, the controller 170 may control the nozzle inspection device 130 to measure the flow rate of the adsorption nozzle 112 again.

When the flow rate of the adsorption nozzle 112 is less than or equal to the predetermined value even after the re-measurement of the flux of the adsorption nozzle 112, the controller 170 may finally determine that the adsorption nozzle 112 is abnormal (e.g., cannot be restored to operational tolerance by the nozzle inspection device 130), and may control the nozzle ejection device 150 to eject the abnormal adsorption nozzle 112 to outside of the mounting apparatus 1000 and/or to replace the abnormal adsorption nozzle 112. This is described in further detail below.

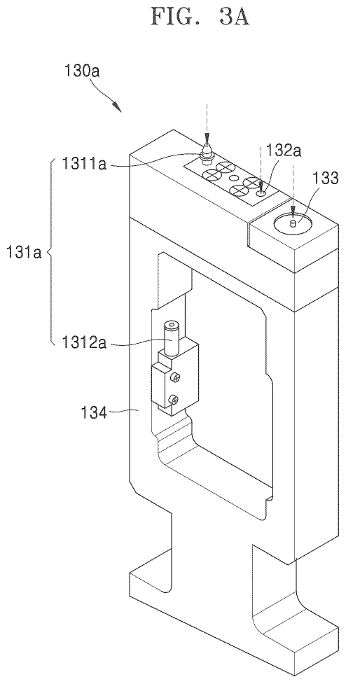

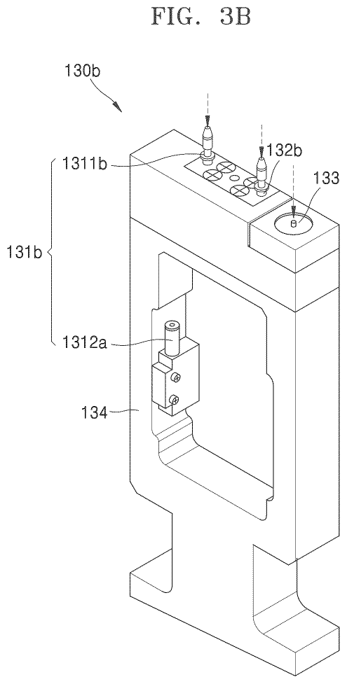

FIG. 3A is a perspective view schematically illustrating an example of the nozzle inspection unit of FIG. 1.

Referring to FIG. 3A, a nozzle inspection device 130a, according to at least some embodiments, includes a nozzle flux inspection portion (or nozzle flux inspection assembly) 131a, a foreign substance removal portion (or foreign substance removal assembly) 132a, and a tension measurement portion (or tension measurement assembly) 133.

The nozzle flux inspection assembly 131a is configured to perform a flux inspection on the adsorption nozzle 112 of the mounting apparatus 1000. As an example, the nozzle flux inspection assembly 131a may include a flow rate generator 1311a and a flux sensor 1312a.

The flow rate generator 1311a is configured to induce a flow of a fluid in the adsorption nozzle 112. The flow rate generator 1311a may protrude from a frame 134. The adsorption nozzle 112 may be located on the flow rate generator 1311a. The flow rate generator 1311a may generate a flow rate in the adsorption nozzle 112.

The flux sensor 1312a is configured to measure a flow rate of a fluid passing through the adsorption nozzle 112. A value measured by the flux sensor 1312a may be transmitted to the controller 170. When the value measured by the flux sensor 1312a is less than a predetermined value, the controller 170 may confirm whether the adsorption nozzle 112 is potentially abnormal.

The foreign substance removal assembly 132a is configured to remove foreign substances from the adsorption nozzle 112. The foreign substance removal assembly 132a may include a blower configured to blow compressed air into the adsorption nozzle 112. The foreign substance removal assembly 132a may be configured to remove foreign substances from the adsorption nozzle 112 by blowing compressed air into the adsorption nozzle 112. For ease of description, the foreign substance removal assembly 132a may be referred as performing a foreign substance removal, and therefore may be considered as having performed the removal even in cases wherein some foreign substance is not removed from the adsorption nozzle 112, in cases wherein the foreign substance causing a reduction in the flow rate is not removed, and/or incases wherein the flow rate reduction is not a result of a foreign substance.

When it is identified that the flow rate within the adsorption nozzle 112 is less than or equal to a predetermined value as an inspection result of the nozzle flux inspection assembly 131a, the controller 170 may control the movement of the adsorption nozzle 112 from the nozzle flux inspection assembly 131a to the foreign substance removal assembly 132a, and may control to remove foreign substances from the adsorption nozzle 112 by using the compressed air within the adsorption nozzle 112.

After potential foreign substances are removed from the adsorption nozzle 112 by the foreign substance removal assembly 132a, the adsorption nozzle 112 may be moved again to the flow rate generator 1311a and a flux may be measured by the flux sensor 1312a. When the measured flux is greater than or equal to a predetermined flux after the foreign substances are removed, the adsorption nozzle 112 may be determined to be in normal condition, mounted again on the head device 110, and used for a mounting process. When the measured flux is below the predetermined flux after the foreign substances are removed, the adsorption nozzle 112 may be determined to be in an abnormal condition and ejected to outside of the mounting apparatus 1000 by the nozzle ejection device 150. This is described in further below.

The tension measurement assembly 133 may measure a tension of a spring within the adsorption nozzle 112. Even when the tension of the spring within the adsorption nozzle 112 is abnormal, the maintaining of pressure within the adsorption nozzle 112 may be weakened and thus the adsorption strength of the adsorption nozzle 112 with respect to the part P may be weakened. A tension value measured by the tension measurement assembly 133 may be transmitted to the controller 170, and the controller 170 may analyze the measured tension value and determine whether the adsorption nozzle 112 is abnormal.

As an example, the tension measurement assembly 133 may include a compression-type load cell. The compression-type load cell is a sensor that measures force or load, and may detect a compressive force applied from the outside and convert the compressive force into an electrical signal. When the adsorption nozzle 112 is disposed on the tension measurement assembly 133 that is a compression-type load cell, the tension measurement assembly 133 may measure a tension of a spring within the adsorption nozzle 112. A value measured by the tension measurement assembly 133 may be transmitted to the controller 170, and the controller 170 may analyze the measured value and determine whether the adsorption nozzle 112 is abnormal. For example, when the tension of the spring is determined to be under an operational threshold value, the adsorption nozzle 112 may be determined as abnormal.

FIG. 3B is a perspective view schematically illustrating another example of the nozzle inspection unit of FIG. 1. A description is made together with reference to FIG. 3A, and thus a repeated descriptions of elements that are the same as and/or substantially similar to those described in reference to FIG. 3A are briefly made or omitted below.

Referring to FIG. 3B, a nozzle inspection device 130b shown in FIG. 3B has a difference with the nozzle inspection device 130a shown in FIG. 3A, in the flow rate generator 1311a of the nozzle flux inspection assembly 131a and the foreign substance removal assembly 132a. That is, a flow rate generator 1311b of a nozzle flux inspection portion (or assembly) 131b shown in FIG. 3B may have a protruding shape having a greater height and width than the flow rate generator 1311a of the nozzle flux inspection assembly 131a shown in FIG. 3A. Also, a foreign substance removal portion (or assembly) 132b shown in FIG. 3B may have a protruding shape having a greater height and width than the foreign substance removal assembly 132a shown in FIG. 3A. The adsorption nozzle 112 may be various in size and shape, and the flow rate generator 1311b and foreign substance removal assembly 132b of FIG. 3B may be used corresponding to a great size of the adsorption nozzle 112.

Referring to FIG. 1, the part supply device 140 is configured to supply parts P. The parts P supplied by the part supply device 140 may be picked up by the head device 110 and be mounted on the substrate 10.

As an example, the part supply device 140 may include a feeder base 141 and at least one feeder 142.

For example, a plurality of feeders 142 may be arranged side by side in a first direction (e.g., the X-direction) on the feeder base 141. The feeder 142 and the feeder base 141 may be detachably coupled to a side portion of the mounting apparatus 1000.

Although not shown, the feeder 142 may consist of a feeder body and a reel, as an example. The reel may be mounted on the feeder body to rotate. A part supply tape on which parts are disposed (or accepted) may be wound on the reel. The part supply tape may have transfer holes formed in a lengthwise direction and having a constant pitch, and these transfer holes may be configured to be sequentially fitted to sprocket gears that rotate at pitch intervals with respect to the feeder body. Therefore, as the sprocket gears rotate at pitch intervals, the part supply tape may be moved while being unwound from the reel at pitch intervals, and an end of the part supply tape may be arranged in a part supply position formed at an upper end of the feeder body. Accordingly, the parts P accepted at intervals on the part supply tape may be sequentially moved to and arranged in the part supply position according to the movement of the pitch intervals.

Meantime, the parts P supplied from each feeder 142 may be parts of different sizes.

The nozzle ejection device 150 may be arranged at one side of the part supply device 140, and may eject the abnormal adsorption nozzle 112 to outside of the mounting apparatus 1000. That is, as described above, the flux was measured firstly in the nozzle inspection device 130, foreign substances were removed, and then the flux was measured secondly, but the adsorption nozzle 112 where a measured flux value was less than or equal to a predetermined value even after the foreign substances are removed may be finally determined as the abnormal adsorption nozzle 112 by the controller 170. The abnormal adsorption nozzle 112 may be ejected to outside of the mounting apparatus 1000 by the nozzle ejection device 150.

In the inventive concepts, a process of inspecting and ejecting the abnormal adsorption nozzle 112 is performed automatically without human intervention, thereby reducing the man-hours required for checking, inspecting, and ejecting the abnormal adsorption nozzle 112. During the process of inspecting and ejecting the abnormal adsorption nozzle 112, the mounting apparatus 1000 may perform a mounting process without interruption, thereby improving process productivity.

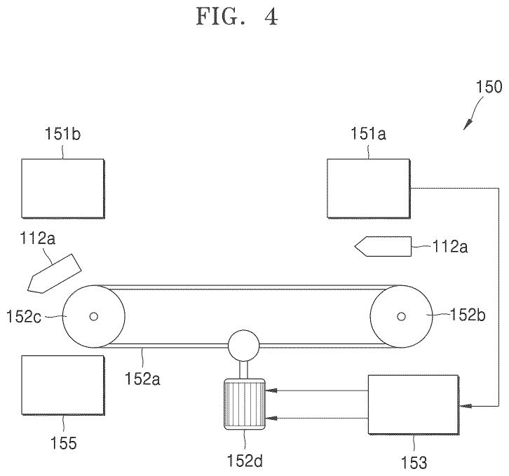

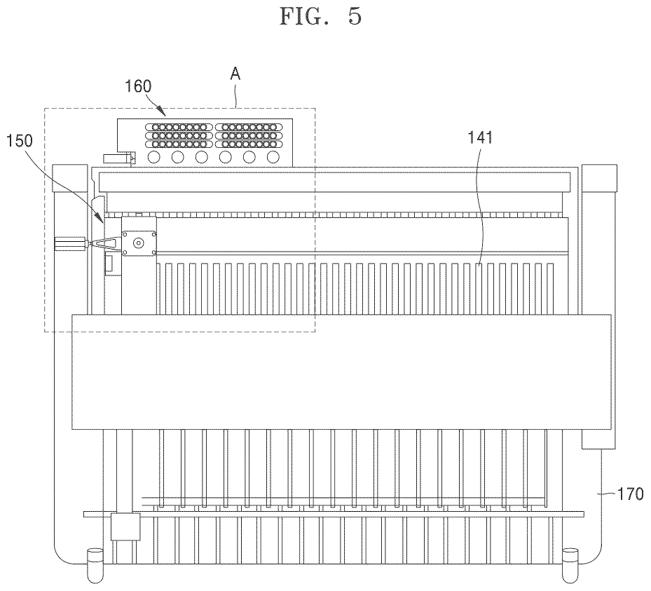

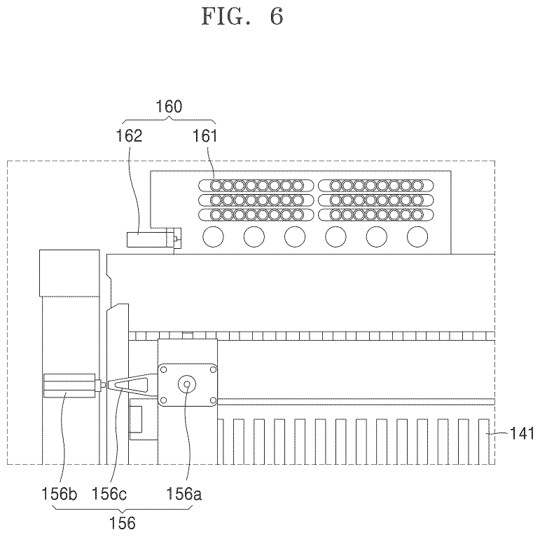

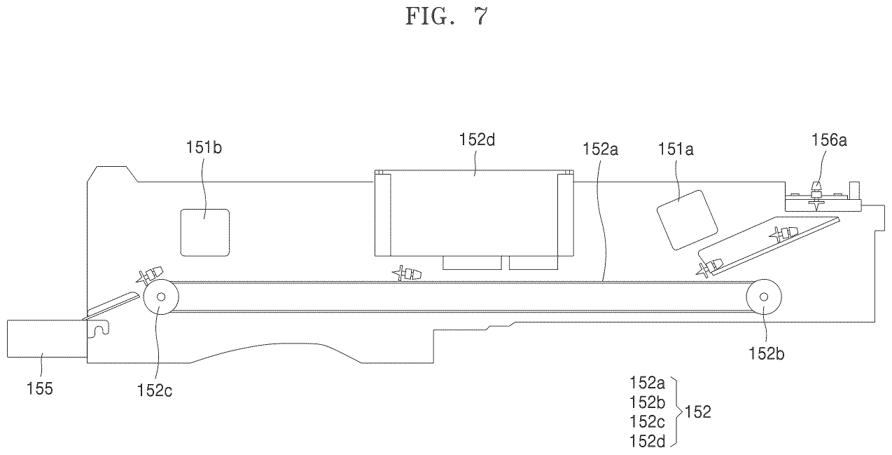

FIG. 4 is a construction diagram schematically illustrating the nozzle ejection unit of FIG. 1. FIG. 5 is a plan view illustrating an example of the nozzle ejection unit of FIG. 1, and FIG. 6 is an enlarged view illustrating a portion A of FIG. 5. FIG. 7 is a side view schematically illustrating the nozzle ejection unit of FIG. 5.

As an example, the nozzle ejection device 150 may include a first sensing portion (or first sensing assembly) 151a, a second sensing portion (or second sensing assembly) 151b, a nozzle transfer portion (or nozzle transfer assembly) 152, a nozzle ejection portion (or nozzle ejection assembly) 155, and a nozzle separation portion (or nozzle separation assembly) 156.

The nozzle separation assembly 156 is configured to separate an abnormal adsorption nozzle 112a from the head device 110. When the nozzle inspection device 130 determines that the adsorption nozzle 112a is abnormal, the abnormal adsorption nozzle 112a may be moved to the nozzle separation assembly 156 and be separated from the head device 110 by the nozzle separation assembly 156.

As an example, the nozzle separation assembly 156 may include a nozzle input port 156a, a nozzle separation driving portion (or nozzle separation driving assembly) 156b, and a connection portion (or connection assembly) 156c.

The nozzle input port 156a may include an opening through which the abnormal adsorption nozzle 112a may be input to the nozzle input port 156a. The nozzle input port 156a may be formed to be larger than the diameter of the adsorption nozzle 112a and thus adsorption nozzles 112a having various diameters may be input to the nozzle input port 156a.

The nozzle separation driving assembly 156b may provide a driving force of separating the adsorption nozzle 112a from the head device 110. The nozzle separation driving assembly 156b may include, for example, a pneumatic cylinder and/or a hydraulic cylinder.

One side of the connection assembly 156c may be connected to the nozzle separation driving assembly 156b, and the other side of the connection assembly 156c may be located at the nozzle input port 156a. The connection assembly 156c may hold the adsorption nozzle 112a within the nozzle input port 156a by driving the nozzle separation driving assembly 156b.

For example, one end of the connection assembly 156c may be connected to a piston rod of the nozzle separation driving assembly 156b. When the nozzle separation driving assembly 156b pushes the piston rod outward by internal pressure, the connection assembly 156c connected to the piston rod may move toward the nozzle input port 156a. As the connection assembly 156c may move inside the nozzle input port 156a, the diameter of the opening of the nozzle input port 156a may decrease. Accordingly, the adsorption nozzle 112a arranged in the nozzle input port 156a may be caught between the other end of the connection assembly 156c and an inner wall of the nozzle input port 156a. As the head device 110 is raised in a state where the adsorption nozzle 112a is in close contact between the other end of the connection assembly 156c and the inner wall of the nozzle input port 156a, the adsorption nozzle 112a may be separated from the head device 110.

When the piston rod of the nozzle separation driving assembly 156b is pushed into the nozzle separation driving assembly 156b by the internal pressure of the nozzle separation driving assembly 156b, the connection assembly 156c connected to the piston rod may also move toward the nozzle separation driving assembly 156b along the piston rod, and accordingly, the adsorption nozzle 112a within the nozzle input port 156a may freely fall inside the nozzle ejection device 150.

The first sensing assembly 151a may detect the adsorption nozzle 112a that is separated by the nozzle separation assembly 156 and heads to the nozzle transfer assembly 152. The adsorption nozzle 112a separated by the nozzle separation assembly 156 may freely fall and be placed on the nozzle transfer assembly 152. The first sensing assembly 151a may detect the adsorption nozzle 112a that freely falls.

The first sensing assembly 151a, which detects the adsorption nozzle 112a that freely falls, may transmit a signal to a motor controller 153 of the nozzle transfer assembly 152. The motor controller 153 may drive step motors 152b, 152c, and 152d of the nozzle transfer assembly 152 based on the signal transmitted from the first sensing assembly 151a.

The second sensing assembly 151b may detect the adsorption nozzle 112a ejected to the nozzle ejection assembly 155. The adsorption nozzle 112 that is separated by the nozzle separation assembly 156 and is placed on the nozzle transfer assembly 152 may be transferred toward the nozzle ejection assembly 155 by the nozzle transfer assembly 152. The nozzle ejection assembly 155 may be located at one end of the nozzle transfer assembly 152, and the adsorption nozzle 112a that has reached one end of the nozzle transfer assembly 152 may be input to the nozzle ejection assembly 155. The second sensing assembly 151b may detect the adsorption nozzle 112a input to the nozzle ejection assembly 155 at one end of the nozzle transfer assembly 152.

The second sensing assembly 151b, configured to detect the adsorption nozzle 112a being deposited to the nozzle ejection assembly 155, may transmit a signal to the motor controller 153 of the nozzle transfer assembly 152 upon detecting the adsorption nozzle 112a being deposited to the nozzle ejection assembly 155. The motor controller 153 may stop the step motors 152b, 152c, and 152d of the nozzle transfer assembly 152 based on the signal transmitted from the second sensing assembly 151b.

Thus, the nozzle transfer assembly 152 may transfer the adsorption nozzle 112a separated by the nozzle separation assembly 156, to the nozzle ejection assembly 155.

As an example, the nozzle transfer assembly 152 may include a conveyor belt 152a and the step motors 152b, 152c, and 152d. The nozzle transfer assembly 152 may further include and/or be connected to the motor controller 153. In at least one embodiment, the motor controller 153 may be included in the controller 170.

The conveyor belt 152a may move in one direction by the driving force of the step motors 152b, 152c, and 152d. The adsorption nozzle 112a, which is separated by the nozzle separation assembly 156 and freely falls, may be located on the conveyor belt 152a. The first sensing assembly 151a may detect the adsorption nozzle 112a that freely falls, and the motor controller 153, which receives a fall detection signal from the first sensing assembly 151a, may drive the step motors 152b, 152c, and 152d and drive the conveyor belt 152a.

The conveyor belt 152a may be located between the step motors 152b and 152c spaced apart from each other. As shown in FIG. 4 according to at least one embodiment, another step motor 152d may be located below the conveyor belt 152a.

The nozzle ejection assembly 155 may eject the adsorption nozzle 112a separated by the nozzle separation assembly 156 to outside of the mounting apparatus 1000. One end of the nozzle ejection assembly 155 may be located at one side of the nozzle transfer assembly 152, and the other end of the nozzle ejection assembly 155 may be connected to outside of the mounting apparatus 1000. That is, the adsorption nozzle 112a may be transferred by the nozzle transfer assembly 152, and may be input to the nozzle ejection assembly 155 when reaching the end of the nozzle transfer assembly 152. The adsorption nozzle 112a may be ejected to outside of the mounting apparatus 1000 along the nozzle ejection assembly 155.

The nozzle exchange device 160 may provide replaceable adsorption nozzles. As described above, the adsorption nozzle 112a determined to be abnormal may be separated from the head device 110 and ejected to outside of the mounting apparatus 1000 by the nozzle ejection device 150. The nozzle exchange device 160 may hold a plurality of normal adsorption nozzles that may replace the abnormal adsorption nozzle 112a. After the abnormal adsorption nozzle 112a is separated and ejected, the head device 110 may mount the normal adsorption nozzle that is being held by the nozzle exchange device 160.

As an example, the nozzle exchange device 160 may include a nozzle holder 161, a nozzle exchange cylinder 162, and a camera (not shown).

The nozzle holder 161 may hold a plurality of replaceable adsorption nozzles.

The nozzle exchange cylinder 162 may provide a driving force for mounting the held adsorption nozzle on the head device 110. The nozzle exchange cylinder 162 may be a pneumatic cylinder or a hydraulic cylinder. The nozzle exchange cylinder 162 may push a piston rod (not shown) outward and/or pull it inward by internal pressure of the nozzle exchange cylinder 162. The nozzle exchange cylinder 162 may fix the adsorption nozzle 112 arranged within the nozzle holder 161 by pushing the piston rod toward the nozzle holder 161. The head device 110 may mount the adsorption nozzle 112 thereon while the nozzle exchange cylinder 162 presses toward the adsorption nozzle 112. After the head device 110 mounts the adsorption nozzle 112 thereon, the piston rod of the nozzle exchange cylinder 162 may move inside the nozzle exchange cylinder 162, and accordingly, a holding force of the nozzle holder 161 for the adsorption nozzle 112 may decrease. Thereafter, the adsorption nozzle 112 may be separated from the nozzle holder 161 by raising the head device 110 on which the adsorption nozzle 112 is mounted.

The camera may photograph and/or monitor replaceable adsorption nozzles. The camera may photograph the replaceable adsorption nozzle 112 that is being held by the nozzle holder 161. A captured image of the adsorption nozzle 112 may be transmitted to the controller 170. The controller 170 may analyze the image of the adsorption nozzle 112 and determine whether the replaceable adsorption nozzle 112 is properly affixed and/or abnormal.

After the adsorption nozzle 112 is inspected by the nozzle inspection device 130, the controller 170 may determine whether the adsorption nozzle 112 is abnormal, and may control the nozzle ejection device 150 to eject the abnormal adsorption nozzle 112.

In at least some embodiments, as noted above, when it is determined that the adsorption nozzle 112 is potentially abnormal, the controller 170 may remove foreign substances from the adsorption nozzle 112 and then may control the nozzle inspection device 130 to inspect again whether the adsorption nozzle 112 is abnormal.

After the adsorption nozzle 112 is inspected again by the nozzle inspection device 130, when it is determined that the adsorption nozzle 112 is abnormal, the controller 170 may control the nozzle ejection device 150 to eject the abnormal adsorption nozzle 112.

Additionally, in at least some embodiments, when no replaceable adsorption nozzle exists in the nozzle exchange device 160, the controller 170 may control to generate a warning sound and stop the mounting apparatus 1000 from operating, or keep the mounting apparatus 1000 operating without replacement of the adsorption nozzle 112. The controller 170 may stop a loading or unloading function for the abnormal adsorption nozzle 112.

So far, the inventive concepts have been described with reference to the embodiments shown in the drawings, but these are merely illustrative, and those skilled in the art will understand that various modifications and other equivalent embodiments are possible therefrom. Therefore, the true scope of technical protection of the inventive concepts should be defined by the technical spirit of the attached claims.

While the inventive concepts have been particularly shown and described with reference to embodiments thereof, it will be understood that various changes in form and details may be made therein without departing from the spirit and scope of the following claims.

What is claimed is:

1. A nozzle inspection device for a mounting apparatus, the nozzle inspection device comprising:
a nozzle flux inspection assembly configured to perform a flux inspection on an adsorption nozzle of the mounting apparatus;
a foreign substance removal assembly configured to remove foreign substances from the adsorption nozzle; and
a tension measurement assembly configured to measure a tension of a spring within the adsorption nozzle.

2. The nozzle inspection device of claim 1, wherein
the foreign substance removal assembly is configured to perform a foreign substance removal based on a determination that a flux of the adsorption nozzle is less than or equal to a predetermined value, and
the nozzle flux inspection assembly is configured to perform the flux inspection on the adsorption nozzle again such that a second flux inspection is performed after the foreign substance removal assembly performs the removal of the foreign substances.

3. The nozzle inspection device of claim 1, wherein the nozzle flux inspection assembly comprises:
a flow rate generator configured to induce a flow of a fluid in the adsorption nozzle; and
a flux sensor configured to measure a flux of the fluid passing through the adsorption nozzle.

4. The nozzle inspection device of claim 1, wherein the foreign substance removal assembly comprises a blower configured to blow compressed air into the adsorption nozzle.

5. The nozzle inspection device of claim 1, wherein the tension measurement assembly comprises a compression-type load cell.

6. A nozzle ejection device for a mounting apparatus, the nozzle ejection device comprising:
a nozzle separation assembly configured to separate an adsorption nozzle from a head device of the mounting apparatus;
a nozzle ejection assembly configured to eject the adsorption nozzle separated by the nozzle separation assembly to outside of the mounting apparatus; and
a nozzle transfer assembly configured to transfer the adsorption nozzle separated by the nozzle separation assembly to the nozzle ejection assembly.

7. The nozzle ejection device of claim 6, wherein the nozzle separation assembly comprises:
a nozzle input port configured to receive the adsorption nozzle;
a nozzle separation driving assembly configured to provide a driving force for separating the adsorption nozzle from the head device; and
a connection assembly connected at one side to the nozzle separation driving assembly and including another side in the nozzle input port, and configured to hold the adsorption nozzle by the driving force of the nozzle separation driving assembly.

8. The nozzle ejection device of claim 7, wherein the nozzle separation driving assembly comprises at least one of a pneumatic cylinder or a hydraulic cylinder.

9. The nozzle ejection device of claim 7, wherein the nozzle transfer assembly comprises:
a conveyor belt configured to move the adsorption nozzle separated by the nozzle separation assembly to the nozzle ejection assembly; and
a step motor configured to provide a driving force to the conveyor belt.

10. The nozzle ejection device of claim 6, further comprising:
a first sensing assembly configured to detect the adsorption nozzle that is separated by the nozzle separation assembly and headed to the nozzle transfer assembly; and
a second sensing assembly configured to detect the adsorption nozzle ejected to the nozzle ejection assembly.

11. A mounting apparatus comprising:
a part supply device configured to supply parts to be mounted;
a head device comprising an adsorption nozzle, the head device configured to load and unload the parts;
a nozzle inspection device configured to inspect the adsorption nozzle and to remove foreign substances from the adsorption nozzle;
a nozzle ejection device configured to eject the adsorption nozzle based on a determination that the inspected adsorption nozzle is abnormal;
a nozzle exchange device configured to provide replaceable adsorption nozzles; and
a controller configured to determine whether the adsorption nozzle is abnormal based on a result of the inspection of the adsorption nozzle by the nozzle inspection device, and to control the nozzle ejection device to eject the abnormal adsorption nozzle.

12. The mounting apparatus of claim 11, wherein the controller is further configured to control the nozzle inspection device to perform a removal of the foreign substances from the adsorption nozzle based on a determination that the head device is performing abnormally and then to control the nozzle inspection device to again inspect whether the adsorption nozzle is abnormal after the removal of the foreign substances is performed.

13. The mounting apparatus of claim 12, wherein the controller is further configured to control the nozzle ejection device to eject the abnormal adsorption nozzle based on a determination that the adsorption nozzle is abnormal after being inspected again.

14. The mounting apparatus of claim 11, wherein, based on a determination that the nozzle exchange device does not include the replaceable adsorption nozzles, the controller is further configured to initiate generating a warning sound and to stop the mounting apparatus from operating.

15. The mounting apparatus of claim 11, wherein the nozzle inspection device comprises:
a nozzle flux inspection assembly configured to perform a flux inspection on the adsorption nozzle of the mounting apparatus;
a foreign substance removal assembly configured to remove foreign substances from the adsorption nozzle; and
a tension measurement assembly configured to measure a tension of a spring within the adsorption nozzle.

16. The mounting apparatus of claim 15, wherein the nozzle flux inspection assembly comprises:
a flow rate generator configured to induce a flow of a fluid in the adsorption nozzle; and
a flux sensor configured to measure a flux of the fluid passing through the adsorption nozzle.

17. The mounting apparatus of claim 11, wherein the nozzle ejection device comprises:
a nozzle separation assembly configured to separate the adsorption nozzle from the head device of the mounting apparatus;
a nozzle ejection assembly configured to eject the adsorption nozzle separated by the nozzle separation assembly to outside of the mounting apparatus;
a nozzle transfer assembly configured to transfer the adsorption nozzle separated by the nozzle separation assembly to the nozzle ejection assembly;
a first sensing assembly configured to detect the adsorption nozzle that is separated by the nozzle separation assembly and headed to the nozzle transfer assembly; and
a second sensing assembly configured to detect the adsorption nozzle ejected to the nozzle ejection assembly.

18. The mounting apparatus of claim 17, wherein the nozzle separation assembly comprises:
a nozzle input port configured to receive the adsorption nozzle;
a nozzle separation driving assembly configured to provide a driving force for separating the adsorption nozzle from the head device; and
a connection assembly connected at one side to the nozzle separation driving assembly and including another side in the nozzle input port, and configured to hold the adsorption nozzle by driving force of the nozzle separation driving assembly.

19. The mounting apparatus of claim 17, wherein the nozzle transfer assembly comprises:
a conveyor belt configured to move the adsorption nozzle separated by the nozzle separation assembly to the nozzle ejection assembly; and
a step motor configured to provide a driving force to the conveyor belt.

20. The mounting apparatus of claim 11, wherein the nozzle exchange device comprises:
a nozzle holder configured to accept the replacement adsorption nozzles;
a nozzle exchange cylinder configured to provide a driving force for attaching one of the replacement adsorptions nozzle to the head device; and
a camera configured to photograph the attached replaceable adsorption nozzle,
wherein the controller is further configured to analyze an image of the attached replaceable adsorption nozzle captured by the camera and to determine whether the attached replaceable adsorption nozzle is abnormal.
